(19) United States
(12) Patent Application Publication
(10) Pub. No.: US 2023/0364579 A1
(43) Pub. Date: Nov. 16, 2023

(54) ATOMIC LAYER DEPOSITION FOR MANUFACTURING WHETLERITE CARBONS

(71) Applicant: Molecular Products Inc., Louisville, CO (US)

(72) Inventors: James A. Hern, Orlando, FL (US); Richard Mackay, Louisville, CO (US); Christopher Vizcaino, Denver, CO (US)

(21) Appl. No.: 18/196,161

(22) Filed: May 11, 2023

Related U.S. Application Data
(60) Provisional application No. 63/341,810, filed on May 13, 2022.

(51) Int. Cl. B01J 20/06; B01J 20/20; B01J 20/28; B01J 20/32; B01J 20/30; C23C 16/455; C23C 16/40; C23C 16/44; C23C 16/02; C23C 16/442; B01D 53/02

(52) U.S. Cl. CPC B01J 20/06; B01D 53/02; B01J 20/20; B01J 20/28016; B01J 20/2803; B01J 20/28042; B01J 20/3071; B01J 20/3204; B01J 20/3225; B01J 20/3236; C23C 16/0227; C23C 16/40; C23C 16/405; C23C 16/407; C23C 16/408; C23C 16/4417; C23C 16/442; C23C 16/45527; C23C 16/45555; B01D 2253/102; B01D 2253/1124; B01D 2253/25; B01D 2257/2064; B01D 2257/302; B01D 2257/408

(57) ABSTRACT

A metal oxide impregnated activated carbon and a method of making the metal oxide impregnated carbon wherein the application of metal oxide impregnants are chemisorbed to active sites in a pore structure using atomic layer deposition to enable targeted impregnant compositions and configurations on activated carbons used for air purification devices.

### CROSS REFERENCE TO OTHER APPLICATION

This application claims the benefit of and priority to U.S. Provisional Application No. 63/341,810 filed May 13, 2022, the contents of which are incorporated by reference.

### GOVERNMENT FUNDING

This invention was made with Government support under Prime Contract No.: FA807518D0017; Subcontract No.: 854-111084-11; Purchase Order 206010; and Change Order 1 to PO206010 awarded by Joint Program Executive Office for Chemical, Biological, Radiological and Nuclear Defense (JPEO-CBRND) Idea Incubator FY21 Spark Program, Aug. 28, 2020. The Government has certain rights in the invention.

### FIELD OF DISCLOSURE

The method of impregnating activated carbon by the application of metals, metal oxides and metal compounds through an Atomic Layer Deposition (ALD) process for gas phase protection devices and air purification filters.

### BACKGROUND

Chemical impregnation of activated carbon is well known in the art. In particular, impregnated activated carbon is the component of Chemical, Biological, Radiological and Nuclear (CBRN) defense filters that removes a broad range of gas and vapor threat agents. Impregnating untreated activated carbon with selected chemicals (i.e., impregnants) increases the reactivity and adsorption capacity of the activated carbon for a range of gases that would otherwise not be filtered by activated carbon, or would have adsorption capacity too low to be of practical use. Methods, formulations, and applications have been described in both patent literature and in academic journal publications.

In fact, activated carbon, in various forms, has been used as vapor phase adsorbents. Particularly, the activated carbons have been used in cartridges in gas masks, as media in nonwoven webs in filter assemblies, and in many other forms. Impregnants have been added to increase the capacity, efficiency, and usefulness of the carbons to protect against contaminants. Metal and metal oxide formulations have been tested and used commercially throughout the world and have generally been used for personal protection and collective protection in civilian, first responder, and military applications, as well as in industrial settings and for indoor air quality improvements.

In particular, the specific subclass of activated carbons which are impregnated with metals, metal oxides and metal compounds are identified as Whetlerites and were developed in the World War 1 era and used as a source of protection against chemical warfare agents. Specifically, U.S. Pat. No. 1,519,470 discloses the application of copper, zinc, and silver metals and metal oxides as useful for the protection of individuals against arsine, phosphine, acid gases including phosgene, chloropicrin, mustard gas, hydrogen cyanide and chlorine. Generally, impregnants for Whetlerite activated carbons have included metal oxides and organic impregnants. Additional patents also disclose the use of other metal and metal salt impregnants to provide protection against other contaminates, such as cyanogen chloride (U.S. Pat. No. 2,612,434, PO Rockwell and JC Goshorn). U.S. Pat. No. 2,920,050 further discloses a method to improve performance of impregnated activated carbons, particularly under high humidity conditions, and also discloses the extension of potential applications relating to metal salt impregnants beyond personal protection equipment to collective protection. It further discloses the addition of chromium compounds into the Whetlerite formulations. Another patent discloses the use of molybdenum as an impregnant. See, U.S. Pat. No. 2,920,051.

Generally, the metal, metal oxide or metal compound impregnants are most effective when the impregnant particles in the finished product are extremely fine and broadly distributed throughout the activated carbon surface area including the internal pore surfaces.

More recent disclosures have revealed the health hazards associated with the use of hexavalent chromium, and thus, has led to the development of chromium-free formulations. See, U.S. Pat. No. 5,063,196; U.S. Pat. No. 5,492,882. Also, a disclosed improved manufacturing method has been developed to improve the time, safety, and cost by eliminating the use of ammoniacal solutions, and instead using aqueous, non-ammoniacal solutions. See, AU Patent No. 2009288177. The use of zinc and zinc oxides to impregnate activated carbon to create crystallites of specific dimensions has also been disclosed. See, WO2012064507; and U.S. Pat. No. 8,753,434.

The current state of the art manufactures the Whetlerite activated carbons through the use of impregnating solutions that are applied to virgin activated carbon through soaking, spraying, or other similar techniques. Impregnation with metals, i.e., zinc, copper and molybdenum compounds, requires dissolving the metal impregnants with compounds such as carbonates, hydroxy-carbonate, and ammonium salts in complex ammonia solutions. The solutions are applied to the internal meso- and micro-pore structure of the activated carbon. The activated carbon is then dried and heated in stages, in a controlled process, to remove free ammonia and water and convert the metal salts to metal oxides. Specifically, when the process is at higher temperatures the metal compounds decompose into oxides which also produces carbon dioxide, carbon monoxide and ammonia. While this is a technique that impregnates the activated carbons, it poses several problems.

Specifically, the use of ammoniacal impregnating solutions generate gaseous ammonia, which must be scrubbed and removed from the process stream. This removal process generates significant amounts of liquid waste and leads to related environmental, disposal and cost issues. It is undesirable for the finished product (i.e. the sorbent) to contain any residual ammonia, as it can desorb under certain use conditions and cause exposure to respirator users, causing both discomfort and irritation. In addition, the heat treatment process converts the applied metal compounds to the oxides by thermal decomposition, and the product must be heated to a temperature high enough to affect the conversion reaction, without causing ignition of the base activated carbon. Literature on the ignition characteristics and temperatures of carbons can be found in CARBON 37 (1999) 335-346 Characterizing the ignition process of activated carbon. Y Suzin, L.C. Buettner, C.A. LeDuc; THERMOCHIMICA ACTA Vol. 75, Issue 1-2, 15 Apr. 1984, pgs 23-32, Thermal decomposition of the basic copper carbonates malachite and azurite. I.W.M.Brown, K.J.D.Mackenzie, G.J.Gainsford. The similar temperatures for metal compound decomposition and carbon ignition poses a challenge for thermal processing in manufacturing impregnated activated carbons. Higher processing temperatures have also been reported to result in coalescing of impregnant into larger than desirable particles, which has the effect of reducing the gas removal performance of the finished product because the larger particles have a lower surface area. Finally, it is difficult to maintain consistency and duration of higher temperatures during the heat treatment phase. Failure to achieve consistency in temperature may cause variability in the decomposition reactions of impregnant chemicals and can ultimately affect the crystal structures of the impregnants. Other issues include the inability to control the distribution of metal oxides, the possible blocking of micropores which can affect the efficiency of the sorbent, and the migration of metals during processing, all of which affect the sorbent performance of the activated carbon.

For these reasons, it is desirable to seek an activated carbon impregnation method that: (i) does not require the use of ammonia solutions; (ii) targets deposition of metal oxides on active surface sites in the carbon pore structure without requiring thermal decomposition; (iii) achieves a stable, bonded structure to reduce mobility or coalescing of impregnants; and (iv) is capable of reproducible deposition characteristics.

Atomic Layer Deposition (ALD) is an established technology which can be used to avoid the aforementioned problems. In particular, ALD is a gas phase (i.e., chemical vapor) technique for depositing a range of materials on the surface of a substrate. See U.S. Pat. No. 4,058,430. Specifically, ALD is a thin-film deposition technique that uses a gas phase chemical process where precursors react with the surface of the material being treated. This method was first developed for use in production of flat panel displays and was further extended to microelectronics manufacturing. ALD is a better deposition method because it produces very thin films and allows for control of the thickness and composition of the films at an atomic level. In the present state of the art, ALD is used for surface coatings of microelectronics, battery materials, catalysts, protective layers, sintering aids, 3D printing powders and pharmaceutical surface coatings. More recently, due to various application developments, ALD has been applied in the design and manufacture of commercial manufacturing equipment, method development and process improvement. The application developments have also led to an expanded selection and supply of precursors, including metal oxides. A detailed description of the precursors and examples of their application can be found at the following reference: <atomiclimits.com/alddatabase>. There are already disclosures which cover the extension of the ALD method to (1) conformal coatings on particles, rather than on flat or large surfaces (U.S. Pat. No. 6,613,383 S.M. George, J.D. Ferguson, A.W. Weimer); and (2) coatings on porous particles (U.S. Pat. No. 10,214,811 D.M. King and P.R. Lichty). There has also been at least one disclosure which describes incomplete ALD coatings which do not fully form conformal coatings, and instead form incomplete coatings on the particles (WO2021097143 A. Dameron, R. Tracy, J. Burger, C. Gump, A. Broerman).

One of the benefits of ALD is that the process can occur at lower temperatures than the conventional activated carbon impregnation methods. With the correct selection of precursor materials, the precursors diffuse into the pore structure of the activated carbon and chemisorb to the internal pore active sites. Once this process is complete, there is no residual ammonia and the end product is not heated to temperatures near spontaneous ignition temperatures as the mechanism is not thermal decomposition.

However, there are also various challenges associated with the ALD method for impregnating carbon. For example, activated carbon has a high surface area, which can increase the processing time. As another example, activated carbon has an inhomogeneous surface, but the ALD process requires surface sites which are active to the coating precursors, and as such, the surface sites may need to be optimized to increase efficiency of the coating process, the metal dispersion, and the overall effectiveness. As yet another example, the ALD may be applied as incomplete layers which is dependent on the distribution of the active sites, and as such, knowing the distribution of the active sites is critical to determining the distribution and size of discontinuous islands of coating materials.

The prior art teaches the application of catalytic titanium oxide and palladium onto activated carbon by the ALD process. See, WO2021/248069. However, the prior art does not teach or disclose of the use of ALD process to apply Whetlerite coatings (including the deposition of copper, zinc, molybdenum) onto activated carbon. Similarly, there has been no disclosure of the application of the metal impregnated carbons made through an ALD process to be used for vapor phase protection against contaminants. In fact, due to the high regulation in the markets that use Whetlerlites in air purification apparatuses, any changes to a process can require a lengthy and expensive certification process which discourages modifications on the production process of impregnated Whetlerites.

Therefore, there exists a need in the art to impregnate activated carbon (i.e., Whetlerites) by application of metals and metal oxides through an ALD process for gas phase protection devices and air purification apparatuses, such as filters. That ALD process to impregnate activated carbon will at least (i) eliminate the use of ammonia solutions to eliminate ammonia off-gas and odor; (ii) eliminate liquid solvents to reduce downstream waste; and (iii) eliminate thermal decomposition. The improved process will also reduce (i) processing time, (ii) processing cost, (iii) production space, and (iv) metal and metal oxide loading requirements. The improved process may also be optimized to (i) improve the lifetime of the activated carbon, or contaminant breakthrough time, (ii) improve ageing characteristics of the activated carbon, and (iii) control the homogeneity and distribution of the metals.

### SUMMARY

This summary is provided to introduce a selection of concepts in a simplified form that are further described in the detailed description of the disclosure. This summary is not intended to identify key or essential inventive concepts of the claimed subject matter, nor is it intended for determining the scope of the claimed subject matter. Additional objects and advantages associated with the compositions, methods, and processes of the present invention will be appreciated by one of ordinary skill in the art in light of the instant claims, description and examples.

The below describes the use of atomic layer deposition (ALD) to apply metal oxides to the internal pore surfaces of activated carbons that can be used to remove toxic agents from breathing air.

The description provides a method for making metal-oxide impregnated activated carbon prepared by atomic layer deposition (ALD) according to the steps comprising: (1) exposing the activated carbon to a pulse of the first precursor, wherein the first precursor is chemically bonded to the activated carbon; (2) applying a purge of inert gas to remove the excess of unreacted first precursor, (3) exposing the activated carbon to a second precursor, wherein a surface reaction between the activated carbon and the second precursor produces a desired species bonded to the surface of the activated carbon, and (4) applying a purge of inert gas to expel gaseous reaction by-products.

The description more specifically provides that the first and second precursors can be gaseous precursors, and the first precursor is chemically bonded to the activated carbon through chemical adsorption.

The description more specifically provides an activated carbon, 12×30 mesh bituminous coal, prepared by atomic layer deposition (ALD) according to the steps comprising: (1) exposure of 12×30 mesh bituminous coal, to a pulse of the first precursor, diethylzinc, which is chemically bonded to the bituminous coal through chemical adsorption, (2) applying an inert gas such as nitrogen or argon, to the 12×30 mesh bituminous coal to remove the unreacted first precursor, (3) exposing the already treated 12×30 mesh bituminous coal to water vapor to produce the desired ALD coating, zinc oxide, on the 12×30 mesh bituminous coal, and (4) applying an inert gas such as nitrogen or argon, to expel the resulting reaction by-product, ethane.

The description further provides an activated carbon prepared by atomic layer deposition (ALD) according to the steps comprising (1) exposure of activated carbon to a pulse of a first precursor, copper, which is chemically bonded to the activated carbon through chemical adsorption, (2) applying an inert gas such as nitrogen or argon, to the activated carbon to remove unreacted first precursor, (3) exposing the already treated activated carbon to an oxidizing agent, such as water vapor to produce the desired ALD coating, copper oxide, on the activated carbon, and (4) applying an inert gas to expel reaction by-product.

The description also provides that the activated carbon prepared by atomic layer deposition (ALD) may further comprise the exposure of activated carbon to a pulse of zinc precursor either sequentially or simultaneously to the exposure of the activated carbon to the copper precursor.

In the embodiment described herein, the impregnated activated carbons prepared by ALD can be from any source, including but not limited to, coal, peat, coconut shell, nuts, organic polymers and various types of wood and are impregnated with metals and metal oxides for vapor phase protection against contaminants faced by industrial, medical, military and commercial markets.

In the embodiment described herein, the resulting impregnant may be metals and metal oxides, including those generally used to impregnate Chemical, Biological, Radiological, and Nuclear (“CBRN”), industrial multigas and military application activated carbons.

In the embodiment described herein Whetlerite coatings (including, but not limited to, the deposition of copper, zinc, molybdenum, and silver) are coated onto activated carbon. In addition, the detailed description discloses the application of metal impregnated carbons for use in vapor phase protection against contaminants.

### BRIEF DESCRIPTION OF DRAWINGS

The drawings provided herein form part of the specification and illustrate several embodiments of the present invention. The drawings are for illustrative purposes only and should not be construed as limiting the scope of the invention.

FIG. 1. Shows a graph of the surface area of impregnated carbon samples prepared by conventional and atomic layer deposition processes, as determined by the BET method.

FIG. 2. Shows a graph of total pore volume, meso pore volume and micro pore volume of the samples prepared by conventional and ALD processes.

FIG. 3. Shows a graph of Performance of carbons against phosphene as a function of ZnO loading.

FIG. 4. Shows a graph of Performance of carbons against hydrogen cyanide as a function of ZnO loading.

FIG. 5. Shows a graph of Gas Life Performance of ALD carbons against hydrogen cyanide.

FIG. 6. Shows a graph of Gas Life Performance of ALD carbons against sulfur dioxide.

### DETAILED DESCRIPTION

This disclosure as a whole may be best understood by reference to the following detailed description when read in conjunction with the accompanying drawings, drawing descriptions, abstract, background, field of disclosure, and associated headings. It is nevertheless understood that no limitation of the scope of the invention is hereby intended. Such alterations and further modifications in the illustrated devices and such further applications of the principles disclosed and illustrated herein are contemplated as would normally occur to one of skill in the art to which this disclosure relates.

ALD methods require the chemisorption of a precursor compound onto the surface of a substrate. The substrate itself requires the presence of functional groups (such as oxide species) on the surface of the substrate which react with the precursor compound. Preferably, there are a sufficient number of surface functional groups per unit area on the internal pore surfaces of the substrate to provide uniform coverage of the substrate.

The surface of most activated carbon is heterogenous and includes a non-uniform distribution of functional groups. The surface of the activated carbon may be pretreated to change the surface chemistry to optimize the ALD deposition. Pretreatments may include, but are not limited to methods such as acid washing, base washing, chemical or ozone treatment.

Presently described is a metal-oxide impregnated activated carbon derived from an activated carbon precursor. Activated carbons precursors may be generated from a variety of materials, or combinations thereof, which include but are not limited to peat, lignite, sub bituminous and bituminous coal, anthracite, wood, wood dust, wood flour, cotton, linters, coconut, carbohydrates, petroleum pitch, petroleum coke, coal tar pitch, fruit pits, fruit stones, nut shells, nut pits, sawdust, palm, vegetables such as rice hull or straw, synthetic polymer, natural polymer, or lignocellulosic material. As such, activated carbons vary in pore size and in form. The activated carbon precursors are produced into activated carbon using several methods, for example without limitation: chemical activation, thermal activation, or combinations thereof. The precursor in a preferred embodiment is coal, and more particularly a granular bituminous coal in mesh size distributions suitable for air purification applications. However, any suitable precursor, including those listed herein may be utilized. The activated carbon in a preferred embodiment is bituminous coal-based activated carbon because it is known to be used as a base carbon for the manufacture of respiratory protective carbons used in collective protection and personal protective filters. In a preferred embodiment, the activated carbon is 12×30 mesh bituminous coal, but may be other forms of activated carbon.

In a preferred embodiment, there is a first precursor compound and a second precursor compound. However, the first precursor compound could be comprised of a single or multiple precursor compound(s) and as would be understood by a person of ordinary skill in the art, one, two, or more than two precursor compounds may be used as necessary to obtain the desired ALD coating for the activated carbon.

More specifically, in a preferred embodiment there is a first precursor gas and a second precursor gas. The first precursor gas could be comprised of a single or multiple precursor gas(es) and as would be understood by a person of ordinary skill in the art, one, two, or more than two precursor gas(es) may be used as necessary to obtain the desired ALD coating for the activated carbon.

Any metal-containing compound suitable for gas phase deposition and subsequent reaction to form a metal or metal oxide may be used as the first precursor compound. For example, in a preferred embodiment, the first precursor compound used in the ALD impregnation may be derived from a transition metal, excluding those transition metals in Group 3. In another preferred embodiment, for example, the precursor compound is derived from zinc, copper, molybdenum. In other preferred embodiments, the precursor compound for zinc compounds is diethylzinc.

In other embodiments, the carbon maybe pretreated with an acid or a base wash to increase active sites and to facilitate metal oxide depositing.

In a preferred embodiment, a second precursor compound is also used in the impregnation process. For example, the second precursor compound may be water vapor. However, other gases or vapors may be used as a second precursor compound as would be understood by one skilled in the art to obtain the desired ALD coating for the activated carbon.

In a preferred embodiment an inert gas may be used in the ALD impregnation process. In particular, as would be understood by a person of ordinary skill in the art, any of the inert gases may be utilized, however, the preferred inert gas is nitrogen or argon.

The ALD impregnation process generally involves the steps comprising: (1) exposure of the substrate surface to a pulse of the first precursor compound and chemisorption of the first precursor compound onto the substrate, (2) purge of inert gas to remove the excess of unreacted precursor compound, (3) introduction of the second precursor compound followed by surface reaction to produce the desired species bonded to the surface of the substrate, and (4) inert gas purge to expel gaseous reaction by-products.

In a preferred embodiment, the first precursor compound and the second precursor compound are one or more gaseous precursor compounds.

More particularly, an activated carbon can be prepared by ALD according to the steps comprising: (1) exposing the activated carbon to a pulse of the first precursor compound, wherein the first precursor compound is chemically bonded to the activated carbon through chemical adsorption; (2) applying a purge of inert gas to remove the excess of unreacted first precursor compound, (3) exposing the activated carbon to a second precursor compound, wherein a surface reaction between the activated carbon and the second precursor compound produces a desired species bonded to the surface of the activated carbon, and (4) applying a purge of inert gas to expel gaseous reaction by-products.

In a preferred embodiment, the first precursor compound and the second precursor compound are one or more gaseous precursor compounds.

In another preferred embodiment, as is shown in more detail in the following example, the ALD impregnation process first involves exposing the substrate, a U.S. Standard Sieve number range 12×30 mesh bituminous coal, to a pulse of the first precursor compound, diethylzinc, which is chemically bonded to the bituminous coal through chemical adsorption. Second, an inert gas is applied to remove the unreacted first precursor compound. Third, the already treated 12×30 mesh bituminous coal is exposed to the second precursor compound, water vapor, to produce the desired ALD coating, zinc oxide, on the 12×30 mesh bituminous coal. Finally, an inert gas, is applied to expel the resulting reaction by-product, ethane.

In a preferred embodiment, the optimal range of zinc oxide on the activated carbon is 0.5 to 15% by weight. It is understood that the amount of metal oxide may be applied alone or in combination with one or more other desired metal oxides or metals in amounts suitable for Whetlerite type activated carbons.

In another preferred embodiment, the ALD impregnation process first involves exposing the substrate, 12×30 mesh bituminous coal, to a pulse of the first precursor compound, copper, which is chemically bonded to the bituminous coal. Second, an inert gas is applied to remove the unreacted first precursor compound. Third, the already treated 12×30 mesh bituminous coal is exposed to an oxidizing source to produce the desired ALD coating, copper oxide, on the 12×30 mesh bituminous coal.

In a preferred embodiment, the optimal range of copper oxide on the activated carbon is 0.5 to 15% by weight. It is understood that the amount of metal oxide may be applied alone or in combination with one or more other desired metal oxides or metals in amounts suitable for Whetlerite type activated carbons.

In another preferred embodiment, the activated carbon created in the ALD impregnation process may contain 0.5 to 15% zinc oxide, 0.5 to 15% copper oxide, 0.1 to 5% molybdenum oxide, and 0.01 to 5% silver oxide by weight. It is understood that the combination of multiple metals may be advantageous for the reduction of numerous contaminants.

Applying the ALD impregnation may be done on a smaller or large scale level. For example, on a smaller level, impregnation can occur through the use of a small volume, evacuated fluidized bed chamber. As another example, impregnation can occur, through the use of a rotary tool which is performed under a vacuum, and mechanically mixes the carbon by rotation of a chamber to ensure uniform exposure to the reactants.

For both the fluidized bed and rotary tool methods, the substrate activated carbon is loaded into the equipment chamber. The chamber is evacuated to facilitate application of the precursor compound and prevent any gas phase reaction prior to deposition on the substrate surface. The substrate may be dried under vacuum to remove any residual adsorbed water if desired. The first precursor compound is introduced to the evacuated chamber in an amount that targets the desired weight of metal oxide, for example in the range of 1 to 15% by weight. The precursor compound concentration in the chamber can be monitored using mass spectrometry and indicates when the precursor compound concentration has dropped, indicating reaction with the carbon surface. A purge with inert gas is then conducted, followed by introduction of the second precursor compound, for example, water vapor, which reacts with the first precursor compound on the surface to yield metal oxide. The mass spectrometer also monitors the concentration of reaction by-products, and in the final step the chamber is purged of those by-products, the nature of which are determined by the first precursor compound and second precursor compound. For example ethane and water vapor can be part of the by-products of a diethylzinc first precursor compound and water vapor second precursor compound. At the completion of all deposition cycles, the chamber is returned to ambient pressure and the finished product is removed from the chamber.

On a large scale level, ALD coating may be done using equipment that accommodates larger batches of substrate material and equipment to introduce larger amounts of reactants but uses fundamentally the same process as the small-scale equipment. Other large scale designs may use a semi-continuous process where multiple evacuated chambers in series are used to effect the steps in the deposition process, and the substrate material is transferred through the series of chambers to yield the final product.

### Representative Example. ZnO Sample Preparation

A study was conducted in an effort to compare conventional metal oxide impregnation which was detailed in the prior art with ALD metal oxide impregnation. Specifically, after using conventional impregnation and ALD impregnation, the resultant samples were subjected to various quantitative methods to compare the impregnant application performance by comparing sample factors such as bulk density, surface area, pore volumes, zinc oxide content, contaminant breakthrough time, and ageing studies.

For this study, the conventional impregnation samples were manufactured on lab scale equipment generating approximately 1 kg of total material. The conventional impregnation samples were prepared by solution impregnation, wherein zinc carbonate was dissolved in an ammoniacal solution and applied to the substrate activated carbon, specifically 12×30 mesh bituminous coal. The carbon was dried to remove water and ammonia, followed by a thermal treatment. The thermal treatment causes decomposition of the zinc salts to form zinc oxide. A range of zinc oxide loadings from approximately 1%-7.5% by weight were targeted on the activated carbon substrate using this method. Specifically, four samples were used with target loading ranges of 1.0%, 2.5%, 5.0%, and 7.5%. ALD impregnation samples were produced using two types of equipment. First, a research scale fluidized bed reactor generated two 60 gram samples. The target loadings of the two samples were 2.5% and 5.0% zinc oxide. Second, a rotary pilot scale tool was used and generated two 1 kg samples. Target loadings for these two samples were 5.0% and 7.5% zinc oxide. With both types of equipment, identical ALD materials were used.

The ALD deposition method involved the following steps using both types of equipment. First, the substrate (12×30 mesh bituminous coal) was exposed to a pulse of the first precursor diethylzinc, and chemisorption of the first precursor into the substrate. Second, a purge of inert gas was used to remove the excess of the unreacted precursor. Third, a second precursor, water vapor, was introduced, which caused a surface reaction to produce the desired species zinc oxide, bonded to the surface of the substrate. Fourth, the inert gas was again purged to expel gaseous reaction by-products.

The chemical process which takes place under either the fluidized bed reactor or the rotary pilot scale tool is described with the following reactions, wherein [S] is the activated carbon substrate:

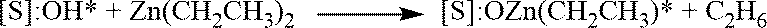

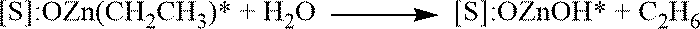

Specifically, as the first precursor diethylzinc reacts with the12×30 mesh bituminous coal, ethane and ethylene are released. Then, the water vapor is added to create the surface reaction and create the wanted ALD coating, the zinc oxide. Thus, the overall reaction is deposition of diethylzinc in the gas phase, and conversion to zinc oxide on the carbon surfaces by reaction with water, followed by inert gas purge to expel ethane.

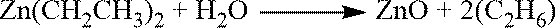

A mass spectrometer located downstream to the reaction bed monitored the ALD deposition cycles and confirmed this reaction. Specifically, how each precursor reacts with a particular functional group on the carbon substrate. For example, the diethyl zinc concentration decays and the spike in ethane and ethylene concentration are seen in the mass spectra. In particular, the diethyl zinc mass fragment is recorded, and the ethane and ethylene fragment concentrations are recorded. An understanding of these reactions is required for high precision manufacturing, and as such this confirmation through mass spectrometry is important in optimizing ALD processing.

The sample preparation phase demonstrated the feasibility of zinc oxide deposition on the high surface area of bituminous coal activated carbon. In fact, both the fluid bed and rotary tools successfully generated functional loadings of zinc oxide on bituminous coal activated carbon. The actual zinc oxide loadings were measured by Inductively Coupled Plasma (ICP) spectroscopy.

### Representative Example. Surface Area and Pore Structure of ZnO Sample

The physical properties of the samples prepared by the conventional process and ALD process were characterized by conventional methods. Specifically, density was measured by ASTM D2854 Standard Test Method for Apparent Density of Activated Carbon. The samples generally showed increasing density with increasing ZnO loading as expected for both conventional and ALD deposition processes.

The surface areas and pore volumes were calculated from N₂ isotherm data. Specifically, an analysis of surface areas was performed using a traditional BET-nitrogen adsorption analysis using a Quantachrome Autosorb iQ-XR system. The pore volume analysis was performed using a Quenched Solid Density Functional Theory (QSDFT) slit pore geometry model which calculates pore size taking into account the effects of surface roughness and chemical heterogeneity. Results are shown in Table 1.

TABLE 1

BET surface area and pore volumes

| Sample Type | % ZnO by ICP | BET Surface Area m2/g | Total Pore Volume cc/g | Mesopore Volume cc/g | Micropore Volume cc/g |
|---|---|---|---|---|---|
| Base Carbon Substrate | 0.0 | 1201 | 0.60 | 0.16 | 0.44 |
| Conventional Process | 0.9 | 1159 | 0.56 | 0.13 | 0.43 |
| Conventional Process | 2.7 | 1000 | 0.53 | 0.12 | 0.41 |
| Conventional Process | 5.4 | 985 | 0.47 | 0.11 | 0.36 |
| Conventional Process | 7.5 | 978 | 0.36 | 0.12 | 0.47 |
| ALD Fluid Bed | 1.9 | 1124 | 0.55 | 0.13 | 0.42 |
| ALD Fluid Bed | 5.6 | 961 | 0.47 | 0.11 | 0.36 |
| ALD Rotary Tool | 4.4 | 943 | 0.47 | 0.13 | 0.35 |
| ALD Rotary Tool | 5.7 | 872 | 0.44 | 0.11 | 0.32 |

As shown in Table 1, the conventional impregnation method reflected that the total measured surface area decreased with increasing levels of impregnant loadings. This is an expected result in the manufacture of metal impregnated activated carbon. In particular, Table 1 reflects that as the zinc oxide load increased, the total pore volume, mesopore volume, and micropore volume decreased.

As shown in Table 1, the ALD depositions of zinc oxide revealed similar changes in surface area and pore volume with zinc oxide loading.

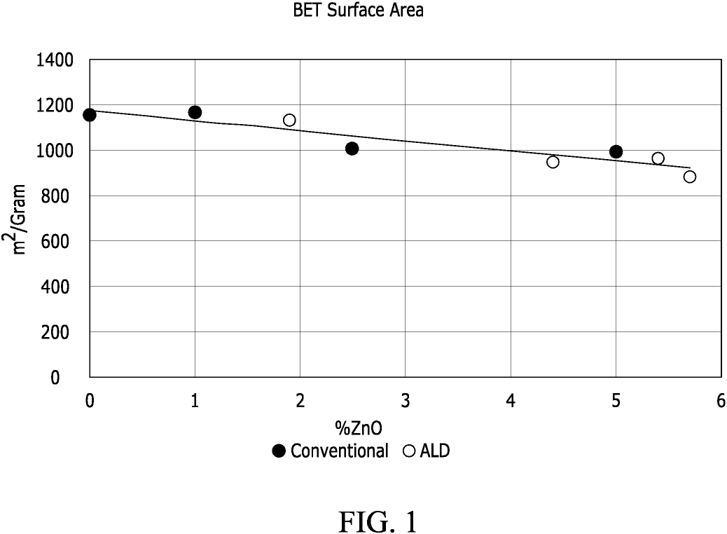

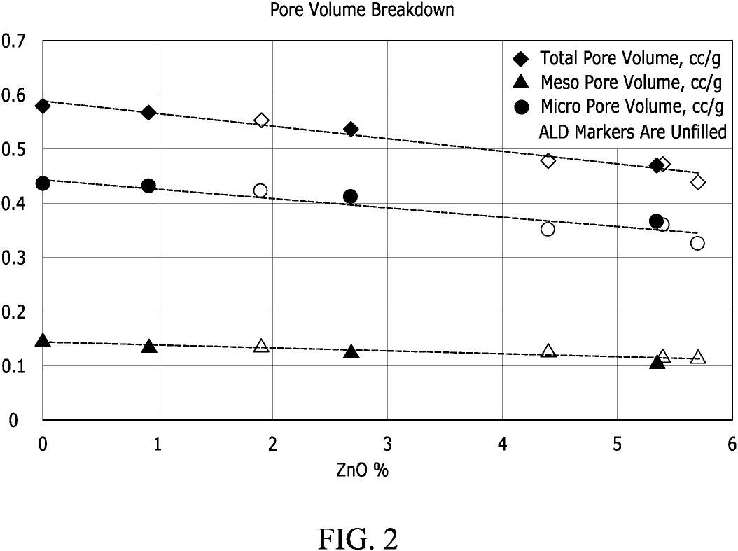

As shown in FIG. 1, the surface area of impregnated carbon samples prepared by conventional and ALD processes, followed the same trendline with ZnO loading. FIG. 2 shows similar results for all of the samples in pore volume analysis. These results strongly support that the ALD deposition process results in deposition on the internal surfaces of the pore structure of the activated carbon and is not an exclusively “line of sight” deposition on the surface of the carbon granules. Impregnation on the internal structure of the carbon is an essential requirement for effective agent/contaminant removal if the activated carbon is used for vapor phase protection against contaminants faced by industrial, military and commercial markets. If the deposition was exclusively on the external surface of granules, very poor agent/contaminant removal would be expected.

### Representative Example. Copper Oxide Sample Preparation

The ALD deposition method involved the following steps using rotary lab scale ALD equipment. The high surface area carbon was coated with copper oxide using a copper precursor. The copper precursor was dosed based on the calculated quantity to achieve the desired copper oxide mass loading. After loading the copper precursor into the reactor, a mass spectrometer was used to periodically sample the chamber. The reaction was determined to be complete once the peaks for byproducts of the reaction all came to a level 3 decades below the carrier gas. After the reaction was complete, the second reactant (i.e., second precursor) was dosed to complete the reaction. The actual copper loadings were measured by Inductively Coupled Plasma (ICP) spectroscopy.

### Representative Example. Copper Oxide and Zinc Oxide Preparation

A composite coating comprising both copper oxide and zinc oxide was prepared using the following steps. The high surface area carbon was first coated with copper oxide using a copper precursor, as previously described, then subsequently coated with ZnO using the same method as the zinc oxide sample preparation previously described.

In addition to the example above where copper was deposited first, followed by zinc, it can be performed in the opposite order. The simultaneous application of copper and zinc precursors may also be performed. These variables in order of application of impregnants may affect the performance of the finished products.

### Representative Example. Agent Removal Performance Testing - Phosgene

The ability of ALD-applied impregnants to remove toxic agents from the airstream was compared to the same characteristic under the conventional impregnation method. The metal impregnants increase the reaction and sorbent capacity to remove both agents from the test airstream compared to virgin activated carbon.

Tube tests were chosen to evaluate the activated carbon sorbents, similar to conditions described in MIL-DTL-32101B specification for ASZM-TEDA. This specification covers activated carbon impregnated with copper, silver, zinc and molybdenum salts and triethylenediamine (TEDA) for use as a sorbent for all known and suspected military chemical weapons agents. The test measures the time required to measure a specified breakthrough concentration of the test agent when exposed to a high incoming concentration. As such, impregnated activated carbon must remove a very high concentration efficiently to reduce the effluent concentration below the breakthrough concentration.

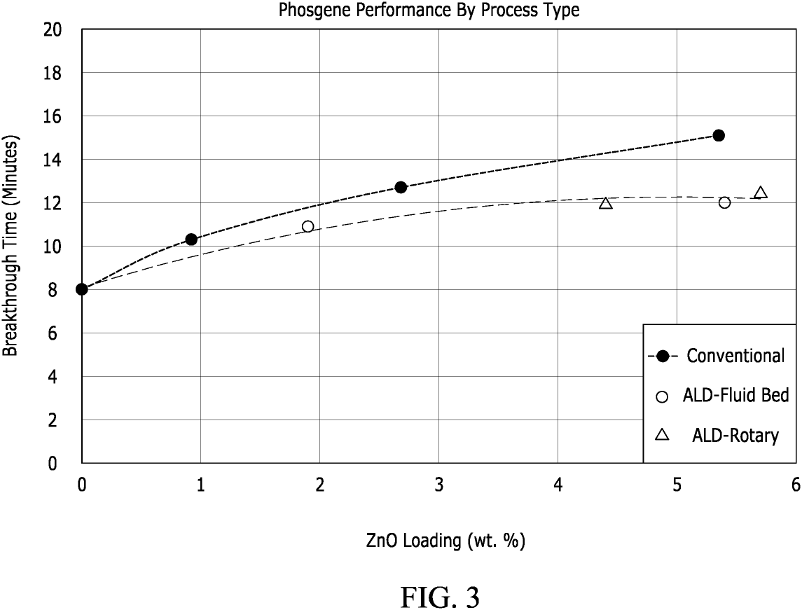

Reporting for all samples tested is in minutes from the start of the test to the specified breakthrough concentration. As shown in FIG. 3, which depicts performance of carbons against phosgene as a function of ZnO loading, the protection level against phosgene increased with increasing amount of ZnO on the carbon. It also showed similar protection can be achieved with samples prepared by ALD method in comparison to the samples prepared by conventional method. At ZnO loadings above 4%, the ALD sample test times were 83% of the conventional samples test times. As such, a person of ordinary skill in the art would understand that optimization of the ALD impregnation methods would likely increase the breakthrough times. FIG. 3 also shows the similarity between ALD samples prepared in a Fluidized Bed and those prepared in a Rotary Tool, showing the capability of preparing Whetlerite carbons by the ALD process for gas phase contaminant protection is independent of the specific reactor configuration.

### Representative Example. Agent Removal Performance Testing - Hydrogen Cyanide

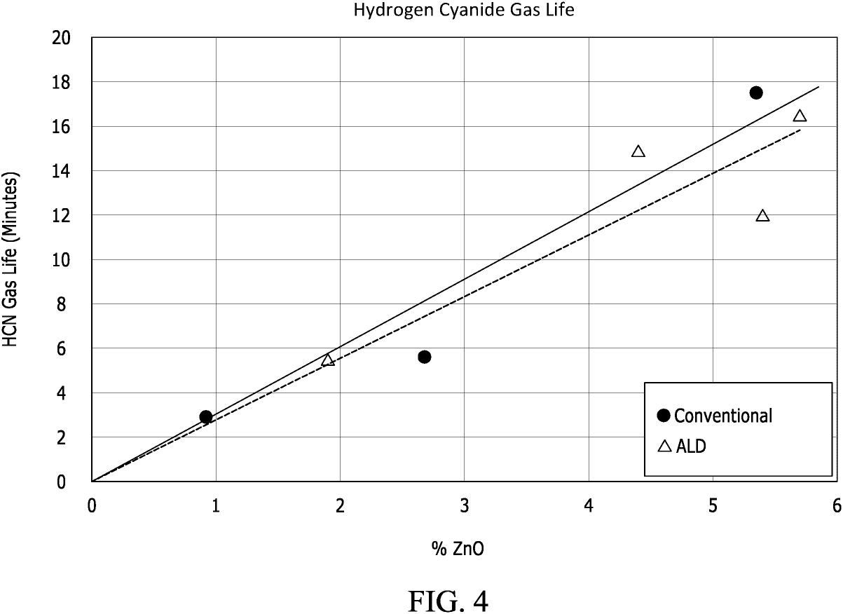

A similar setup for the testing described previously for Phosgene was used to determine the agent removal performance of the ALD prepared carbons against hydrogen cyanide. Reporting for all samples tested is in minutes from the start of the test to the specified breakthrough concentration, which is defined as the sum of HCN and (CN)₂ concentration. As shown in FIG. 4, which depicts gas life performance of carbons against hydrogen cyanide as a function of ZnO loading, the protection level against hydrogen cyanide increased with increasing amount of ZnO on the carbon. It also showed the similar protection achieved with samples prepared by ALD method in comparison to the samples prepared by conventional method. In general, the ALD deposition yielded good performance in reaction with hydrogen cyanide when compared to conventional process samples.

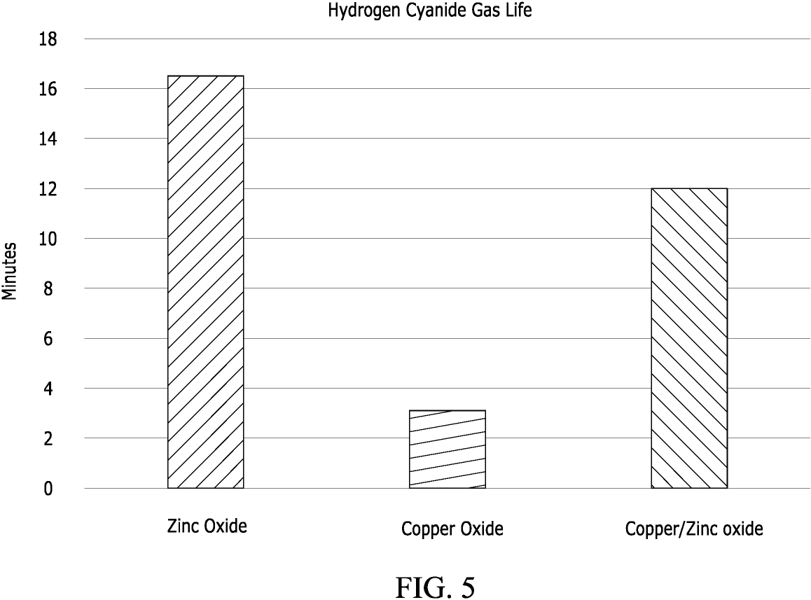

Additional data were collected on ALD prepared carbon samples with copper only, and with combined copper and zinc oxide depositions. In examples depicted in FIG. 5, the gas life performance of ALD carbons against hydrogen cyanide, inform that the ALD prepared samples provide protection against hydrogen cyanide, and the level of protection is dependent on the amount and composition of the metal impregnants.

### Representative Example. Agent Removal Performance Testing - Sulfur Dioxide

In addition to the ability of ALD-applied impregnants to remove toxic agents from the airstream, the ALD-applied agents can also reduce harmful industrial emissions. Specifically, sulfur dioxide (SO₂). This gas was selected because zinc and copper oxides and combinations thereof can also increase the sorbent capacity to reduce SO₂ from test airstreams when compared to virgin activated carbon.

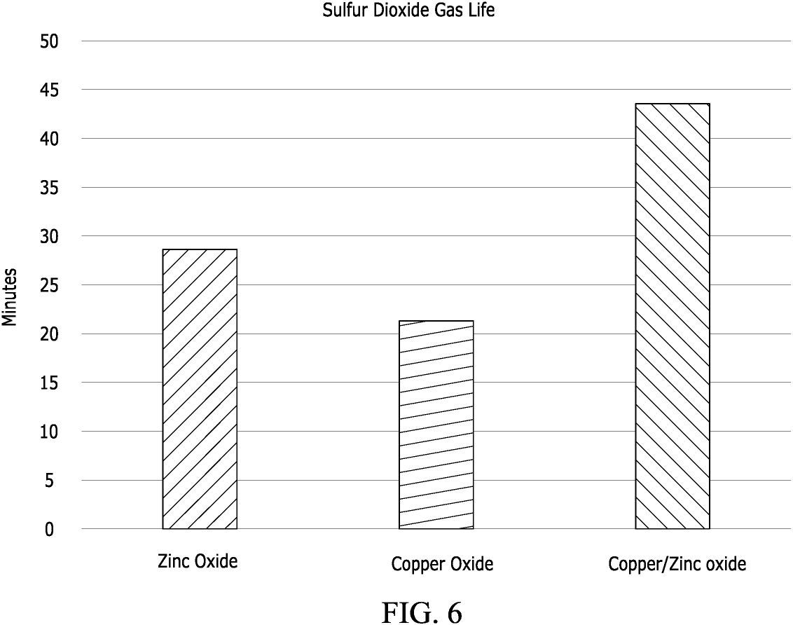

Reporting for all samples tested are in minutes from the start of the test to the specified breakthrough concentration.. As shown in FIG. 6, the gas life performance of ALD carbons against sulfur dioxide informs that the protection level against sulfur dioxide was highest with the combined zinc and copper oxide impregnation on the carbon. The ALD deposition yielded effective performance in protecting against sulfur dioxide contaminants.

### Representative Example. Analysis of Results

The comparison studies reflect that ALD impregnation is a feasible option for the impregnation of Whetlerite type products. Specifically, the ALD impregnated product had comparable performance to the conventional impregnated products. More particularly, the ALD impregnation method achieved deposition success as determined by the generation of zinc oxide loadings in a desired range. Additionally, the physical properties of the ALD impregnated activated carbon were consistent with those made by the conventional impregnation method. Specifically, the density, surface area, and pore volumes values of the ALD samples were very similar to the conventional samples. Moreover, the toxic and industrial gas reduction tests also showed successful deposition of the impregnants. The test times increased with increasing loading of impregnant, which is a result generally seen with impregnated activated carbons. This supports the ALD impregnation was successful in generating functional impregnants on the base activated carbon. For both hydrogen cyanide and phosgene, the conventional and ALD process yielded comparable results across the range of loadings produced. In addition, the ALD process was capable of reducing a common industrial acid gas, SO₂.

These results support a broad array of beneficial uses for ALD to impregnate activated carbon with metal, metal oxides, and metal compound impregnates, including gas phase protection against air contaminates and vapor phase protection against air contaminates. These properties support a use of the present disclosure to provide both gas phase and vapor phase protection against chemical warfare agents. The present disclosure will be further beneficial when incorporated into personal protective equipment (PPE), and in collective protective protection equipment by traditional means. The disclosure may, for example be incorporated into PPE to satisfy the standards required by the National Institute for Occupational Safety and Health (NIOSH), the Europäishe Norm (EN), the safety standards of any national or international governing body, and the safety standards of the U.S. Military. The present disclosure will be beneficial to provide protection against toxic industrial chemicals/materials (TICs/TIMs). As would be obvious to one of ordinary skill in the art, the present disclosure will provide gas and vapor phase protection against air contaminates in commercial, military, and residential situations.

These results support the use of ALD to impregnate activated carbons with the desired metal, metal oxide and metal compound impregnants. As would be obvious to one of ordinary skill in the art, the present disclosure may use a single metal oxide on activated carbon, two metal oxides or a bimetallic oxide on activated carbon, three metal oxides or a trimetallic oxide on activated carbon, four metal oxides on activated carbon, or any combination of oxides on activated carbon.

The foregoing examples have been provided merely for the purpose of explanation, and are in no way to be construed as limiting of the present disclosure. While described with reference to various embodiments, it is understood that the words, which have been used herein, are words of description and illustration, rather than words of limitation. Further, although the invention has been described herein with reference to particular means, materials, and embodiments, the disclosure is not intended to be limited to the particulars set forth herein; rather, the disclosure extends to all functionally equivalent structures, methods and uses. Those skilled in the art, having the benefit of the teachings of this disclosure, may affect numerous modifications thereto and changes may be made without departing from the scope and spirit of the aspects hereof.

Any other undisclosed or incidental details of the construction or composition of the various elements of any embodiment of the present disclosure are not believed to be critical to the achievement of the advantages hereof, so long as the elements possess the attributes needed for them to perform as disclosed. Certainly, one skilled in the field would be able to conceive of a wide variety of alternative configurations and successful combinations thereof. The selection of these and other details of construction are believed to be well within the ability of one of even rudimental skills in this area, in view of the present disclosure. Illustrative embodiments have been described in considerable detail for the purpose of disclosing a practical, operative composition whereby this disclosure may be practiced advantageously. The examples described herein are intended to be exemplary only. The novel characteristics of the disclosure may be incorporated in other forms without departing from the spirit and scope of the disclosure. This disclosure encompasses embodiments both comprising and consisting of the elements described with reference to the illustrative embodiments. All technical terms shall take on their customary meaning as established by the appropriate technical discipline utilized by those normally skilled in that particular art area.

1. A process of depositing one or more metal oxides onto an activated carbon substrate by atomic layer deposition comprising:
exposing the activated carbon to a pulse of the first precursor compound, wherein the first precursor compound is chemically bonded to the activated carbon through chemical adsorption,
applying a purge of inert gas to remove the excess of unreacted first precursor compound,
exposing the activated carbon to a second precursor compound, wherein a surface reaction between the first precursor compound applied to the activated carbon surface, and the second precursor compound produces a desired reaction product bonded to the surface of the activated carbon, and
applying a purge of inert gas to expel reaction by-products.

2. The process of claim 1 wherein the first precursor compound is a first gaseous precursor.

3. The process of claim 2 wherein the first gaseous precursor comprises a metal, metal oxide, or combinations thereof.

4. The process of claim 1 wherein the second precursor compound is a second gaseous precursor.

5. The process of claim 4 wherein the second gaseous precursor is selected to yield a metal oxide as the reaction product.

6. The process of claim 1 wherein the desired reaction product is a transition metal.

7. The process of claim 3, wherein the first gaseous precursor comprises zinc, copper, molybdenum, silver, or any combination thereof.

8. The process of claim 4, wherein the second gaseous precursor is water vapor.

9. The process of claim 4, wherein the second gaseous precursor is an oxidizing source.

10. The process of claim 1, wherein the first precursor compound and second precursor compound are different compounds.

11. The process of claim 1, further comprising repeating the process one or more times.

12. The process of claim 11, wherein a new first precursor compound is selected during each process, and wherein a new second precursor compound is selected during each process.

13. The process of claim 12, wherein the first precursor compound and second precursor compound are different compounds.

14. The process of claim 1, wherein the activated carbon substrate is derived from wood, peat, coconut, coal, pitch, fruit stones, nut shells, or other suitable carbonaceous material.

15. The process of claim 1, wherein the activated carbon substrate is preferably derived from granular bituminous coal.

16. The process of claim 1, wherein the activated carbon substrate is preferably derived from granular coconut shell.

17. The process of claim 1, wherein the activated carbon substrate is in a powder, granular, extruded or monolithic form.

18. The process of claim 1, further comprising pretreating the activated carbon substrate by an acid washing process or a base washing process.

19. The process of claim 1, further comprising pretreating the activated carbon substrate using a reducing reagent or an oxidizing reagent.

20. A filter media for removing gas phase contaminants comprising:
a substrate, wherein the substrate comprises an activated carbon; and
one or more metal oxides, wherein the one or more metal oxides is impregnated on the activated carbon comprising the method of:
exposing the activated carbon to a pulse of the first precursor compound, wherein the first precursor compound is chemically bonded to the activated carbon through chemical adsorption,
applying a purge of inert gas to remove the excess of unreacted first precursor compound,
exposing the activated carbon to a second precursor compound, wherein a surface reaction between the first precursor compound applied to the activated carbon surface, and the second precursor compound produces a desired reaction product bonded to the surface of the activated carbon, and
applying a purge of inert gas to expel gaseous reaction by-products.

21. The filter media substrate of claim 20 wherein the metal oxide is impregnated on the activated carbon in a range of 0-25 % by weight.

22. The filter media substrate of claim 20 wherein the one or more metal oxides comprises a Group 4 metal selected from a group consisting of titanium, zirconium, hafnium, rutherfordium, or any combination thereof.

23. The filter media substrate of claim 20 wherein the one or more metal oxides comprises a Group 6 metal selected from a group consisting of chromium, molybdenum, tungsten, seaborgium, or any combination thereof.

24. The filter media substrate of claim 23 wherein the one or more metal oxides is Molybdenum oxide.

25. The filter media substrate of claim 20 wherein the one or more metal oxides comprises a Group 11 metal selected from a group consisting of copper, silver, gold, roentgenium, or any combination thereof.

26. The filter media substrate of claim 25 wherein the one or more metal oxides is copper oxide.

27. The filter media substrate of claim 25 wherein one of the one or more metal oxides is silver oxide.

28. The filter media substrate of claim 20 wherein the one or more metal oxides comprises a Group 12 metal is selected from a group consisting of zinc, cadmium, mercury, copernicium or any combination thereof.

29. The filter media substrate of claim 28 wherein one of the one or more metal oxides is zinc oxide.
